(19) United States
(12) Patent Application Publication
(10) Pub. No.: US 2024/0155892 A1
(43) Pub. Date: May 9, 2024

(54) DISPLAY DEVICE

(71) Applicant: Samsung Display Co., LTD., Yongin-si (KR)

(72) Inventors: Junhyun LEE, Yongin-si (KR); Dong-Ho KIM, Yongin-si (KR); Seongyun LEE, Yongin-si (KR)

(21) Appl. No.: 18/235,275

(22) Filed: Aug. 17, 2023

(30) Foreign Application Priority Data
Nov. 8, 2022 (KR) 10-2022-0147987

(51) Int. Cl. H10K 59/131; H01L 23/00; H10K 59/90

(52) U.S. Cl. CPC H10K 59/131; H01L 24/05; H01L 24/06; H01L 24/29; H01L 24/32; H10K 59/90; H01L 2224/05624; H01L 2224/05639; H01L 2224/05644; H01L 2224/05647; H01L 2224/05686; H01L 2224/06152; H01L 2224/29028; H01L 2224/32145; H01L 2224/32225

(57) ABSTRACT

A display device includes: a substrate including a display area and a pad area, the pad area being located around the display area and adjacent to one side of the display area; a flexible printed circuit board disposed in the pad area on the substrate and including a first bump part and a plurality of test points connected to the first bump part; a driving integrated circuit disposed in the pad area on the substrate, spaced apart from the flexible printed circuit board and including a second bump part; a signal line disposed in the pad area on the substrate and connecting the first bump part and the second bump part; and a plurality of control parts disposed in the pad area on the substrate and connected to the signal line between the first bump part and the second bump part.

This application claims priority to Korean Patent Application No. 10-2022-0147987 filed on Nov. 8, 2022, and all the benefits accruing therefrom under 35 U.S.C. § 119, the content of which in its entirety is herein incorporated by reference.

### BACKGROUND

### 1. Field

Embodiments relate to a display device. More specifically, embodiments relate to a foldable display device including a switching transistor.

### 2. Description of the Related Art

As information technology develops, importance of a display device, which is communication media between a user and information, is being highlighted. Accordingly, the use of the display device such as a liquid crystal display device, an organic light emitting display device, a plasma display device, and the like is increasing.

The display device includes a display area and a non-display area. In the display area of the display device, a driving element (e.g., a transistor) and a light emitting element (e.g., an organic light emitting diode) that emits light by receiving a voltage or signal from the driving element are disposed, so that a predetermined image may be displayed. An image is not displayed in the non-display area where the light emitting element is not disposed. In the non-display area of the display device, a driving integrated circuit, a pad, or the like are disposed to provide the voltage or signal to the light emitting element.

### SUMMARY

Embodiments provide a display device with improved emission characteristics.

A display device according to an embodiment of the present disclosure includes: a substrate including a display area and a pad area, the pad area being located around the display area and adjacent to one side of the display area; a flexible printed circuit board disposed in the pad area on the substrate and including a first bump part and a plurality of test points connected to the first bump part; a driving integrated circuit disposed in the pad area on the substrate, spaced apart from the flexible printed circuit board and including a second bump part; a signal line disposed in the pad area on the substrate and connecting the first bump part and the second bump part; and a plurality of control parts disposed in the pad area on the substrate and connected to the signal line between the first bump part and the second bump part.

In an embodiment, the plurality of control parts may include: a first control part connected to the first bump part and a second control part connected to the second bump part.

In an embodiment, the number of the plurality of test points may be four.

In an embodiment, the flexible printed circuit board may further include a third bump part spaced apart from the first bump part, and the driving integrated circuit may further include a fourth bump part spaced apart from the second bump part.

In an embodiment, the display device may further include a first connection line connecting the first bump part and the third bump part.

In an embodiment, the display device may further include a second connection line spaced apart from the first connection line and connecting the second bump part and the fourth bump part.

In an embodiment, the display device may further include a third control part connected to the third bump part and a fourth control part connected to the fourth bump part.

In an embodiment, each of the first, second, third and fourth control parts may include a plurality of transistors.

In an embodiment, each of the plurality of transistors may be a switching transistor.

In an embodiment, the plurality of transistors included in one control part among the first, second, third and fourth control parts may receive the same signal.

A display device according to an embodiment of the present disclosure includes: a substrate including a display area and a pad area, the pad area being located around the display area and adjacent to one side of the display area; a flexible printed circuit board disposed in the pad area on the substrate and including a first bump part, a second bump part spaced apart from the first bump part, a plurality of first test points connected to the first bump part and a plurality of second test points connected to the second bump part; a driving integrated circuit disposed in the pad area on the substrate, spaced apart from the flexible printed circuit board and including a third bump part and a fourth bump part spaced apart from the third bump part; a signal line disposed in the pad area on the substrate and connecting the first bump part and the third bump part and connecting the second bump part and the fourth bump part; and a plurality of control parts disposed in the pad area on the substrate and connected to the signal line.

In an embodiment, the plurality of control parts may include: a first control part connected to the first bump part, a second control part connected to the second bump part, a third control part connected to the third bump part, and a fourth control part connected to the fourth bump part.

In an embodiment, the number of the plurality of first test points and the number of the plurality of second test points may each be four.

In an embodiment, the signal line may include a first signal line and a second signal line spaced apart from the first signal line. The first signal line may connect the first bump part and the third bump part, and the second signal line may connect the second bump part and the fourth bump part.

In an embodiment, the first signal line may connect the first control part and the third control part.

In an embodiment, the second signal line may connect the second control part and the fourth control part.

In an embodiment, each of the first, second, third and fourth control parts may include a plurality of transistors.

In an embodiment, each of the plurality of transistors may be a switching transistor.

In an embodiment, the plurality of transistors included in one control part among the first, second, third and fourth control parts may receive the same signal.

In an embodiment, the plurality of transistors included in each of the first control part and the second control part may receive a first signal, and the plurality of transistors included in each of the third control part and the fourth control part may receive a second signal.

In a display device according to embodiments of the present disclosure, bump parts included in a flexible printed circuit board and bump parts included in a driving integrated circuit may be connected to control parts, respectively. Each of the control parts may include a plurality of switching transistors, and compression resistance of each of the bump parts may be selectively measured according to an operation of the switching transistors. Accordingly, a relatively small number of test points may be required to measure the compression resistance. Accordingly, emission characteristics of the display device may be effectively improved by securing a space of the flexible printed circuit board.

### BRIEF DESCRIPTION OF THE DRAWINGS

FIG. 1 is a plan view illustrating a display device according to an embodiment of the present disclosure.

FIG. 2 is a cross-sectional view taken along line I-I′ of FIG. 1.

FIG. 3 is an enlarged cross-sectional view of area B of FIG. 2.

FIG. 4 is an enlarged plan view of an example of area A of FIG. 1.

FIGS. 5 and 6 are conceptual views for explaining methods of measuring resistance of bump parts.

FIG. 7 is an enlarged plan view of area C of FIG. 4.

FIG. 8 is a cross-sectional view taken along line II-II′ of FIG. 7.

FIG. 9 is a plan view illustrating a display device according to another embodiment of the present disclosure.

FIG. 10 is an enlarged plan view of an example of area D of FIG. 9.

### DETAILED DESCRIPTION

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Hereinafter, embodiments of the present disclosure will be described in more detail with reference to the accompanying drawings. The same reference numerals are used for the same components in the drawings, and redundant descriptions of the same components will be omitted.

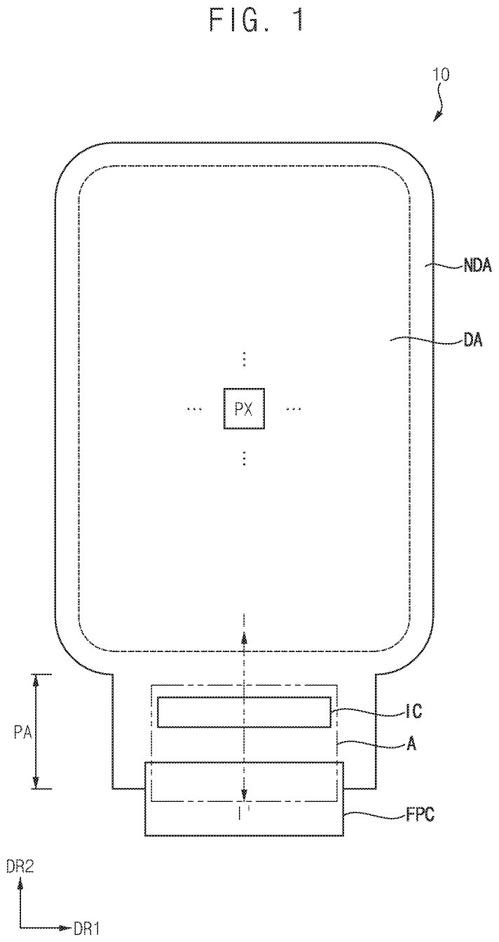

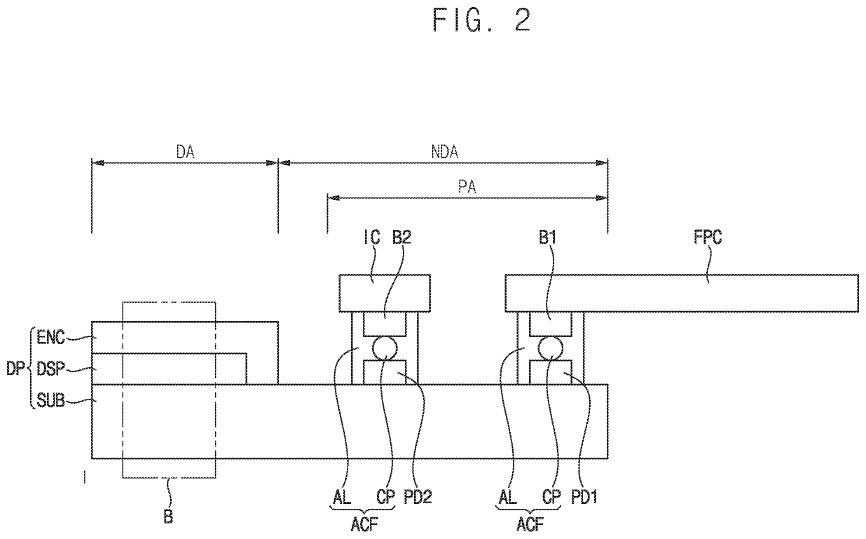

FIG. 1 is a plan view illustrating a display device according to an embodiment of the present disclosure. FIG. 2 is a cross-sectional view taken along line I-I′ of FIG. 1.

Referring to FIGS. 1 and 2, a display device 10 may include a display panel DP, a driving integrated circuit IC, a flexible printed circuit board FPC and an anisotropic conductive film ACF.

The display panel DP may include a substrate SUB, a display unit DSP disposed in the display area DA on the substrate SUB and an encapsulation layer ENC disposed on the display unit DSP and surrounding the display unit DSP. A detailed description of components of the display panel DP will be described later.

The substrate SUB may include a display area DA and a non-display area NDA. The display area DA may be an area capable of displaying an image by generating light or adjusting transmittance of light provided from an external light source. The non-display area NDA may be an area not displaying an image.

A plurality of pixels PX that emits light may be disposed in the display area DA, and accordingly, an image may be displayed in the display area DA. The pixels PX may be arranged in a matrix form along a first direction DR1 and a second direction DR2 crossing the first direction DR1. For example, the second direction DR2 may be perpendicular to the first direction DR1. Each of the pixels PX may include a light emitting element and a pixel circuit for driving the light emitting element. In an embodiment, the light emitting element may include an organic light emitting diode, and the pixel circuit may include at least one thin film transistor.

The non-display area NDA may be located around the display area DA. For example, the non-display area NDA may surround at least a portion of the display area DA. Drivers for driving the pixels PX may be disposed in the non-display area NDA.

The non-display area NDA may include a pad area PA. For example, the pad area PA may be adjacent to a lower portion of the display area DA. The driving integrated circuit IC and the flexible printed circuit board FPC may be disposed in the pad area PA on the substrate SUB.

At least one first pad PD1 and at least one second pad PD2 may be disposed in the pad area PA on the substrate SUB. Each of the first pad PD1 and the second pad PD2 may include a metal, a transparent conductive material, or the like. Examples of metals that may be used as each of the first pad PD1 and the second pad PD2 may include gold (Au), silver (Ag), aluminum (Al), copper (Cu), or the like. Examples of transparent conductive materials that may be used as each of the first pad PD1 and the second pad PD2 may include indium tin oxide (“ITO”), indium zinc oxide (“IZO”), indium zinc tin oxide (“IZTO”), and the like. These may be used alone or in combination with each other.

The first pad PD1 may transmit a voltage, a control signal, or the like output from the flexible printed circuit board FPC to the driving integrated circuit IC. The second pad PD2 may transmit the voltage, the control signal, or the like transmitted from the flexible circuit printed board FPC to the driving integrated circuit IC, and may transmit a voltage, a control signal, or the like output from the driving integrated circuit IC to the pixels PX.

The flexible printed circuit board FPC may be disposed in the pad area PA on the substrate SUB. Specifically, the flexible printed circuit board FPC may partially overlap the pad area PA in a plan view. That is, a first portion of the flexible printed circuit board FPC may overlap the pad area PA in a plan view, and a second portion excluding the first portion of the flexible printed circuit board FPC may not overlap the pad area PA in a plan view. The flexible printed circuit board FPC may provide a voltage, a control signal, or the like to the pixels PX. In an embodiment, when the substrate SUB includes glass, the flexible printed circuit board FPC may have a film-on-glass (“FOG”) structure directly disposed on the substrate SUB. In another embodiment, when the substrate SUB includes a transparent resin substrate, the flexible printed circuit board FPC may have a film-on-plastic (“FOP”) structure directly disposed on the substrate SUB.

The flexible printed circuit board FPC may include at least one first bump B1. The first bump B1 may overlap the first pad PD1 in a plan view. The first bump B1 may include metal. Examples of metals that may be used as the first bump B1 may include gold, silver, aluminum, copper, and the like. These may be used alone or in combination with each other. The first bump B1 may output the voltage, the control signal, or the like provided to the pixels PX from the flexible printed circuit board FPC.

The anisotropic conductive film ACF may be disposed in the pad area PA between the substrate SUB and the flexible printed circuit board FPC. The anisotropic conductive film ACF may bond the first pad PD1 and the first bump B1. Accordingly, the anisotropic conductive film ACF may electrically connect the substrate SUB and the flexible printed circuit board FPC. In an embodiment, the anisotropic conductive film ACF may include an adhesive layer AL and a plurality of conductive particles CP arranged in the adhesive layer AL.

The adhesive layer AL may include an insulating polymer material. Examples of insulating polymer materials that may be used as the adhesive layer AL may include epoxy resin, acrylic resin, phenol resin, melamine resin, diallyl phthalate resin, urea resin, polyimide resin, polystyrene resin, polyurethane resin, polyethylene resin, polyvinyl acetate resin and the like. These may be used alone or in combination with each other.

The conductive particles CP may be disposed between the first pad PD1 and the first bump B1. Accordingly, the conductive particles CP may electrically connect the substrate SUB and the flexible printed circuit board FPC. In an embodiment, each of the conductive particles CP may include a core including an insulating polymer material and a conductive layer surrounding the core and including a conductive metal material.

The driving integrated circuit IC may be disposed in the pad area PA on the substrate SUB. The driving integrated circuit IC may control the voltage, the control signal, or the like provided to the pixels PX. In an embodiment, when the substrate SUB includes glass, the driving integrated circuit IC may have a chip-on-glass (“COG”) structure directly disposed on the substrate SUB. In another embodiment, when the substrate SUB includes a transparent resin substrate, the driving integrated circuit IC may have a chip-on-plastic (“COP”) structure directly disposed on the substrate SUB. However, the present disclosure is not limited thereto, the flexible printed circuit board FPC may be disposed in the pad area on the substrate, and the driving integrated circuit IC may have a chip-on-film (“COF”) structure directly disposed on the flexible printed circuit board FPC in still another embodiment.

The driving integrated circuit IC may include at least one second bump B2. The second bump B2 may overlap the second pad PD2 in a plan view. The second bump B2 may include metal. Examples of metals that may be used as the second bump B2 may include gold, silver, aluminum, copper, and the like. These may be used alone or in combination with each other. The second bump B2 may receive the voltage, the control signal, or the like provided from the flexible printed circuit board FPC, and may output the voltage, the control signal, or the like provided to the pixels PX.

The anisotropic conductive film ACF may be disposed in the pad area PA between the substrate SUB and the driving integrated circuit IC. The anisotropic conductive film ACF may bond the second pad PD2 and the second bump B2. Accordingly, the anisotropic conductive film ACF may electrically connect the substrate SUB and the driving integrated circuit IC.

The anisotropic conductive film ACF may include the adhesive layer AL and the plurality of conductive particles CP arranged in the adhesive layer AL. The conductive particles CP may be disposed between the second pad PD2 and the second bump B2. Accordingly, the conductive particles CP may electrically connect the substrate SUB and the driving integrated circuit IC.

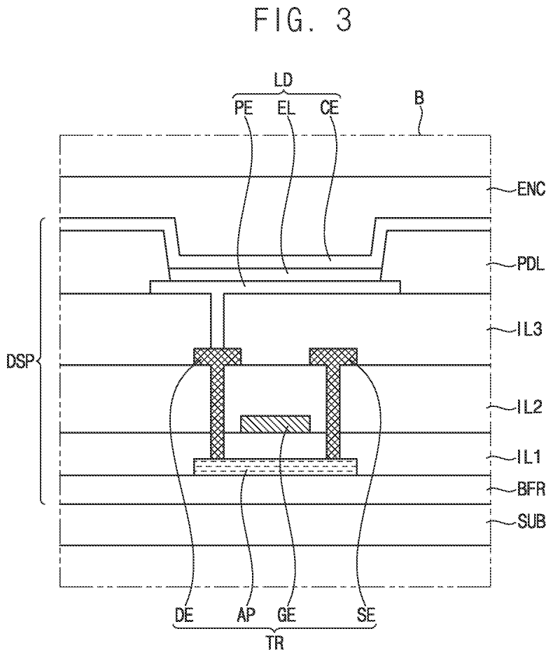

FIG. 3 is an enlarged cross-sectional view of area B of FIG. 2. For example, FIG. 3 may be an enlarged cross-sectional view of the display area DA.

Referring to FIGS. 2 and 3, the display panel DP of the display device 10 may include the substrate SUB, the display unit DSP disposed on the substrate SUB and the encapsulation layer ENC disposed on the display unit DSP. Here, the display unit DSP may include a buffer layer BFR, a transistor TR, a first insulating layer IL1, a second insulating layer IL2, a third insulating layer IL3, a pixel defining layer PDL and a light emitting element LD. The transistor TR may include an active pattern AP, a gate electrode GE, a source electrode SE and a drain electrode DE, and the light emitting element LD may include a pixel electrode PE, a light emitting layer EL and a common electrode CE.

The substrate SUB may include a transparent material or an opaque material. Examples of materials that may be used as the substrate SUB may include polyimide, quartz, glass, and the like. These may be used alone or in combination with each other.

The buffer layer BFR may be disposed on the substrate SUB. The buffer layer BFR may prevent diffusion of metal atoms or impurities from the substrate SUB into the transistor TR. In addition, the buffer layer BFR may improve flatness of a surface of the substrate SUB when the surface of the substrate SUB is not uniform. The buffer layer BFR may include an inorganic insulating material. Examples of inorganic insulating materials that may be used as the buffer layer BFR may include silicon oxide (SiOₓ), silicon nitride (SiNₓ), silicon oxynitride (SiOₓN_{y}), and the like. These may be used alone or in combination with each other.

The active pattern AP may be disposed on the buffer layer BFR. The active pattern AP may have a source area, a drain area and a channel area located between the source area and the drain area. The active pattern AP may include a silicon semiconductor material or an oxide semiconductor material. Examples of silicon semiconductor materials that may be used as the active pattern AP may include amorphous silicon, polycrystalline silicon, and the like. Examples of oxide semiconductor materials that may be used as the active pattern AP may include indium gallium zinc oxide, indium tin zinc oxide, and the like. These may be used alone or in combination with each other.

The first insulating layer IL1 may be disposed on the active pattern AP. The first insulating layer IL1 may sufficiently cover the active pattern AP, and may have a substantially flat top surface without creating a step around the active pattern AP. Optionally, the first insulating layer IL1 may cover the active pattern AP, and may be disposed along a profile of the active pattern ACT with a uniform thickness. The first insulating layer IL1 may include an inorganic insulating material. Examples of inorganic insulating materials that may be used as the first insulating layer IL1 may include silicon oxide, silicon nitride, silicon oxynitride, and the like. These may be used alone or in combination with each other.

The gate electrode GE may be disposed on the first insulating layer IL1. The gate electrode GE may overlap the channel area of the active pattern AP in a plan view. The gate electrode GE may include a conductive material. Examples of conductive materials that may be used as the gate electrode GE may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), copper (Cu), and the like. These may be used alone or in combination with each other.

The second insulating layer IL2 may be disposed on the first insulating layer IL1. The second insulating layer IL2 may sufficiently cover the gate electrode GE, and may have a substantially flat top surface without creating a step around the gate electrode GE. Optionally, the second insulating layer IL2 may cover the gate electrode GE, and may be disposed along a profile of the gate electrode GE with a uniform thickness. The second insulating layer IL2 may include an inorganic insulating material. Examples of inorganic insulating materials that may be used as the second insulating layer IL2 may include silicon oxide, silicon nitride, silicon oxynitride, and the like. These may be used alone or in combination with each other.

The source electrode SE and the drain electrode DE may be disposed on the third insulating layer IL3. The source electrode SE may be connected to the source area of the active pattern AP through a contact hole penetrating first portions of the first insulating layer IL1 and the second insulating layer IL2. The drain electrode may be connected to the drain area of the active pattern AP through a contact hole penetrating second portions of the first insulating layer IL1 and the second insulating layer IL2. Each of the source electrode SE and the drain electrode DE may include a conductive material. Examples of conductive materials that may be used as each of the source electrode SE and the drain electrode DE may include aluminum, platinum, palladium, silver, magnesium, gold, nickel, neodymium, iridium, chromium, lithium, calcium, molybdenum, titanium, tungsten, copper, and the like. These may be used alone or in combination with each other.

Accordingly, the transistor TR including the active pattern AP, the gate electrode GE, the source electrode SE and the drain electrode DE may be disposed in the display area DA on the substrate SUB.

The third insulating layer IL3 may be disposed on the second insulating layer IL2. The third insulating layer IL3 may sufficiently cover the source electrode SE and the drain electrode DE. The third insulating layer IL3 may include an organic insulating material. Examples of organic insulating materials that may be used as the third insulating layer IL3 may include photoresist, polyacrylic resin, polyimide resin, acrylic resin, and the like. These may be used alone or in combination with each other.

The pixel electrode PE may be disposed on the third insulating layer IL3. The pixel electrode PE may be connected to the drain electrode DE of the transistor TR through a contact hole penetrating the third insulating layer IL3. The pixel electrode PE may include a conductive material. Examples of conductive materials that may be used as the pixel electrode PE may include aluminum, platinum, palladium, silver, magnesium, gold, nickel, neodymium, iridium, chromium, lithium, calcium, molybdenum, titanium, tungsten, copper, indium tin oxide, indium zinc oxide, and the like. These may be used alone or in combination with each other.

The pixel defining layer PDL may be disposed on the third insulating layer IL3. An opening exposing at least a portion of the pixel electrode PE may be defined in the pixel defining layer PDL. The pixel defining layer PDL may include an organic insulating material. Examples of organic insulating materials that may be used as the pixel defining layer PDL may include photoresist, polyacrylic resin, polyimide resin, acrylic resin, and the like. These may be used alone or in combination with each other.

The light emitting layer EL may be disposed on the pixel electrode PE. Specifically, the light emitting layer EL may be disposed on the pixel electrode PE exposed by the opening of the pixel defining layer PDL. The light emitting layer EL may include an organic material, and may emit light of a predetermined color.

The common electrode CE may be disposed on the light emitting layer EL and the pixel defining layer PDL. The common electrode CE may include a conductive material. Examples of conductive materials that may be used as the common electrode CE may include aluminum, platinum, silver, magnesium, gold, chromium, tungsten, titanium, and the like. These may be used alone or in combination with each other.

Accordingly, the light emitting element LD including the pixel electrode PE, the light emitting layer EL and the common electrode CE may be disposed in the display area DA on the substrate SUB. The light emitting element LD may emit light based on a driving current transmitted from the transistor TR.

The encapsulation layer ENC may be disposed on the common electrode CE. The encapsulation layer ENC may prevent impurities, moisture, air, and the like from permeating the light emitting element LD from outside. The encapsulation layer ENC may include at least one inorganic layer and at least one organic layer. For example, the encapsulation layer ENC may have a structure in which inorganic layers and organic layers are alternately stacked. The encapsulation layer ENC may include an insulating material.

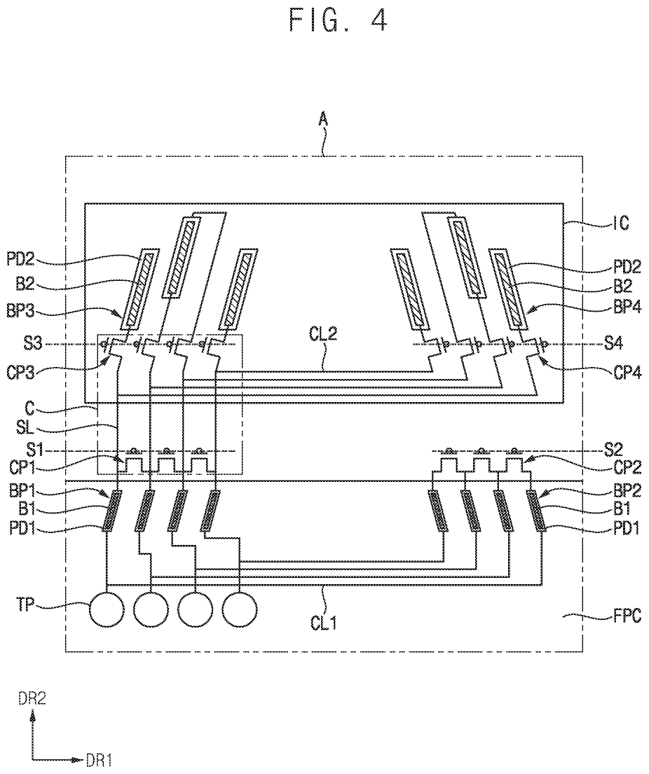

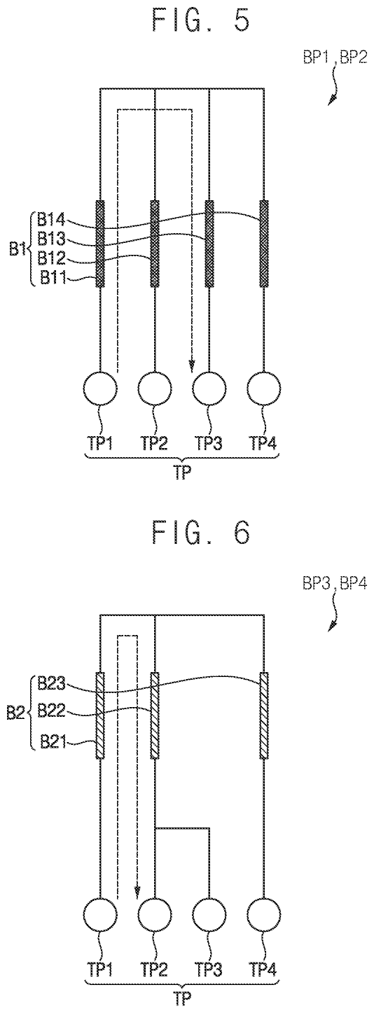

FIG. 4 is an enlarged plan view of an example of area A of FIG. 1. FIGS. 5 and 6 are conceptual views for explaining methods of measuring resistance of bump parts. For example, FIG. 4 may be an enlarged plan view of the pad area PA. FIG. 5 may be a conceptual view for explaining a method of measuring resistance of each of first and second bump parts BP1 and BP2, and FIG. 6 may be a conceptual view for explaining a method of measuring resistance of each of third and fourth bump parts BP3 and BP4. In addition, switching transistors shown in FIG. 4 may be briefly represented by symbols.

Referring to FIGS. 1, 2, 4, 5 and 6, the display device 10 may include the flexible printed circuit board FPC, the driving integrated circuit IC, a signal line SL, a first control part CP1, a second control part CP2, a third control part CP3, a fourth control part CP4, a first connection line CL1 and a second connection line CL2.

The flexible printed circuit board FPC may be disposed in the pad area PA on the substrate SUB. The flexible printed circuit board FPC may include the first bump part BP1, the second bump part BP2 and a plurality of test points TP.

In an embodiment, the second bump part BP2 may be spaced apart from the first bump part BP1 in the first direction DR1. In an embodiment, for example, the first bump part BP1 may be disposed on a left side of the flexible printed circuit board FPC, and the second bump part BP2 may be disposed on a right side of the flexible printed circuit board FPC. The first connection line CL1 may connect the first bump part BP1 and the second bump part BP2.

Each of the first bump part BP1 and the second bump part BP2 may include at least one first bump B1. In an embodiment, for example, the first bump B1 may include a (1-1)th bump B11, a (1-2)th bump B12, a (1-3)th bump B13 and a (1-4)th bump B14. The first bump B1 may overlap the first pad PD1 disposed on the substrate SUB on a plane (i.e., in a plan view). Although FIGS. 4 and 5 illustrate that the number of the first bump B1 and the number of the first pad PD1 each are four, the configuration of the present disclosure is not limited thereto.

The test points TP may be connected to the first bump part BP1 and the second bump part BP2. The test points TP may be electrically connected to a test device (not shown) provided outside the display device 10. Accordingly, compression resistance between the substrate SUB and the flexible printed circuit board FPC and compression resistance between the substrate SUB and the driving integrated circuit IC may be measured through the test points TP. In an embodiment, the number of test points TP may be four. In an embodiment, for example, the test points TP may include a first test point TP1, a second test point TP2, a third test point TP3 and a fourth test point TP4. However, the configuration of the present disclosure is not limited thereto.

The driving integrated circuit IC may be disposed in the pad area PA on the substrate SUB. The driving integrated circuit IC may be disposed spaced apart from the flexible printed circuit board FPC in the second direction DR2 in the pad area PA. The driving integrated circuit IC may include the third bump part BP3 and the fourth bump part BP4.

In an embodiment, the fourth bump part BP4 may be disposed apart from the third bump part BP3 in the first direction DR1. In an embodiment, for example, the third bump part BP3 may be disposed on a left side of the driving integrated circuit IC, and the fourth bump part BP4 may be disposed on a right side of the driving integrated circuit IC. The second connection line CL2 may be spaced apart from the first connection line CL1, and may connect the third bump part BP3 and the fourth bump part BP4.

Each of the third bump part BP3 and the fourth bump part BP4 may include at least one second bump B2. In an embodiment, for example, the second bump B2 may include a (2-1)th bump B21, a (2-2)th bump B22 and a (2-3)th bump B23. The second bump B2 may overlap the second pad PD2 disposed on the substrate SUB on a plane (i.e., in a plan view). Although FIGS. 4 and 6 illustrate that the number of the second bump B2 and the number of the second pad PD2 each are three, the configuration of the present disclosure is not limited thereto.

The signal line SL may be disposed between the first bump part BP1 and the third bump part BP3. The signal line SL may connect the first bump part BP1 and the third bump part BP3. That is, the first bump part BP1 may be connected to the second bump part BP2 through the first connection line CL1, the third bump part BP3 may be connected to the fourth bump part BP4 through the second connection line CL2, and the first bump part BP1 may be connected to the third bump part BP3 through the signal line SL. Accordingly, the test points TP may be electrically connected to each of the first, second, third and fourth bump parts BP1, BP2, BP3 and BP4. Therefore, resistance of each of the first, second, third and fourth bump parts BP1, BP2, BP3 and BP4 may be measured through the test points TP.

The first control part CP1 may be disposed between the first bump part BP1 and the third bump part BP3. However, the present disclosure is not limited thereto. The first control part CP1 may be disposed anywhere as long as connected to the first bump part BP1, and connected to the signal line SL.

The second control part CP2 may be disposed between the second bump part BP2 and the fourth bump part BP4. However, the present disclosure is not limited thereto. The second control part CP2 may be disposed anywhere as long as connected to the second bump part BP2.

The third control part CP3 may be disposed between the first bump part BP1 and the third bump part BP3. However, the present disclosure is not limited thereto. The third control part CP3 may be disposed anywhere as long as connected to the third bump part BP3, and connected to the signal line SL.

The fourth control part CP4 may be disposed between the second bump part BP2 and the fourth bump part BP4. However, the present disclosure is not limited thereto. The fourth control part CP4 may be disposed anywhere as long as connected to the fourth bump part BP4, and connected to the second connection line CL2.

In an embodiment, each of the first, second, third and fourth control parts CP1, CP2, CP3 and CP4 may include a plurality of transistors. In an embodiment, for example, each of the plurality of transistors may be a switching transistor.

Each of the first, second, third and fourth control parts CP1, CP2, CP3 and CP4 may receive the same control signal. In other words, the switching transistors included in one control part among the first, second, third and fourth control parts CP1, CP2, CP3 and CP4 may receive the same control signal. In an embodiment, for example, the switching transistors included in the first control part CP1 may receive a first signal S1, and the switching transistors included in the second control part CP2 may receive a second signal S2. The switching transistors included in the third control part CP3 may receive a third signal S3, and the switching transistors included in the fourth control part CP4 may receive a fourth signal S4. The control signals may be applied to the switching transistors through a data driver (not shown), another test point (not shown), or the like.

In an embodiment, the first, second, third and fourth control parts CP1, CP2, CP3 and CP4 may control resistance measurement of the first, second, third and fourth bump parts BP1, BP2, BP3 and BP4 through the switching transistors, respectively.

In an embodiment, for example, the first signal S1 having a low level may be applied to the first control part CP1, and the second, third and fourth signals S2, S3 and S4 having a high level may be applied to the second, third and fourth control parts CP2, CP3 and CP4, respectively. Accordingly, the switching transistors included in the first control part CP1 may be turned on, and the switching transistors included in the second, third and fourth control parts CP2, CP3 and CP4 may be turned off. In this case, resistance of the first bump part BP1 may be measured. However, the present disclosure is not limited thereto. In another embodiment, the first signal S1 having a high level may be applied to the first control part CP1. Accordingly, the switching transistors included in the first control part CP1 may be turned off. In this case, resistance of at least one of the bump parts excluding the first bump part BP1 may be measured.

For another example, the second signal S2 having a low level may be applied to the second control part CP2, and the first, third and fourth signals S1, S3, and S4 having a high level may be applied to the first, third and fourth control parts CP1, CP3 and CP4, respectively. Accordingly, the switching transistors included in the second control part CP2 may be turned on, and the switching transistors included in the first, third and fourth control parts CP1, CP3 and CP4 may be turned off. In this case, resistance of the second bump part BP2 may be measured. However, the present disclosure is not limited thereto. In another embodiment, the second signal S2 having a high level may be applied to the second control part CP2. Accordingly, the switching transistors included in the second control part CP2 may be turned off. In this case, resistance of at least one of the bump parts excluding the second bump part BP2 may be measured.

Referring to FIG. 5, the resistance of each of the first and second bump parts BP1 and BP2 may be measured through the test points TP. In this case, the first test point TP1 may be a constant current source, and the second test point TP2 may not be used. The third test point TP3 may be a grounding part, and the fourth test point TP4 may be a voltage measurement part. That is, in order to measure the compression resistance of each of the first and second bump parts BP1 and BP2, only three test points TP among the four test points TP may be used.

A current may flow from the first test point TP1 to the third test point TP3. Voltage may be applied by the current to the (1-1)th bump B11 and the (1-3)th bump B13 located on a path of the current. That is, voltage may not be applied to the (1-2)th bump B12 and the (1-4)th bump B14 located outside the path of the current.

In order to measure voltages of opposite ends of the (1-3)th bump B13, voltage of each of the third test point TP3 and the fourth test point TP4 may be measured. If voltage difference is calculated by measuring the voltage of each of the third test point TP3 and the fourth test point TP4 and then divided by the current value flowed through the first test point TP1, compression resistance of the (1-3)th bump B13 may be measured according to Ohm's law (V=I*R). Accordingly, the resistance of each of the first and second bump parts BP1 and BP2 may be measured.

For another example, the third signal S3 having a low level may be applied to the third control part CP3, and the first, second and fourth signals S1, S2, and S4 having a high level may be applied to the first, second and fourth control parts CP1, CP2 and CP4, respectively. Accordingly, the switching transistors included in the third control part CP3 may be turned on, and the switching transistors included in the first, second, and fourth control parts CP1, CP2 and CP4 may be turned off. In this case, resistance of the third bump part BP3 may be measured. However, the present disclosure is not limited thereto. In another embodiment, the third signal S3 having a high level may be applied to the third control part CP3. Accordingly, the switching transistors included in the third control part CP3 may be turned off. In this case, resistance of at least one of the bump parts excluding the third bump part BP3 may be measured.

For another example, the fourth signal S4 having a low level may be applied to the fourth control part CP4, and the first, second third signals S1, S2 and S3 having a high level may be applied to the first, second and third control parts CP1, CP2 and CP3, respectively. Accordingly, the switching transistors included in the fourth control part CP4 may be turned on, and the switching transistors included in the first, second and third control parts CP1, CP2 and CP3 may be turned off. In this case, resistance of the fourth bump part BP4 may be measured. However, the present disclosure is not limited thereto. In another embodiment, the fourth signal S4 having a high level may be applied to the fourth control part CP4. Accordingly, the switching transistors included in the fourth control part CP4 may be turned off. In this case, resistance of at least one of the bump parts excluding the fourth bump part BP4 may be measured.

Referring to FIG. 6, the resistance of each of the third and fourth bump parts BP3 and BP4 may be measured through the test points TP. In this case, the first test point TP1 may be a constant current source, and the second test point TP2 may be a current grounding part. The third test point TP3 may be a voltage grounding part, and the fourth test point TP4 may be a voltage measurement part. That is, in order to measure the compression resistance of each of the third and fourth bump parts BP3 and BP4, all four test points TP may be used.

A current may flow from the first test point TP1 to the second test point TP2. Voltage may be applied by the current to the (2-1)th bump B21 and the (2-2)th bump B22 located on a path of the current. That is, voltage may not be applied to the (2-3)th bump B23 located outside the path of the current.

In order to measure voltages of opposite ends of the (2-2)th bump B22, voltage of each of the third test point TP3 and the fourth test point TP4 may be measured. If voltage difference is calculated by measuring the voltage of each of the third test point TP3 and the fourth test point TP4 and then divided by the current value flowed through the first test point TP1, compression resistance of the (2-2)th bump B22 may be measured according to Ohm's law (V=I*R). Accordingly, the resistance of each of the third and fourth bump parts BP3 and BP4 may be measured.

Although FIG. 4 illustrates that each of the first control part CP1 and the second control part CP2 includes three transistors and each of the third control part CP3 and the fourth control part CP4 includes four transistors, the configuration of the present disclosure is not limited thereto.

In addition, although FIGS. 5 and 6 illustrate that the first test point TP1, the second test point TP2, the third test point TP3 and the fourth test point TP4 are sequentially arranged from left to right, the configuration of the present disclosure is not limited thereto. For another example, the first test point TP1, the second test point TP2, the third test point TP3 and the fourth test point TP4 may be sequentially arranged from right to left.

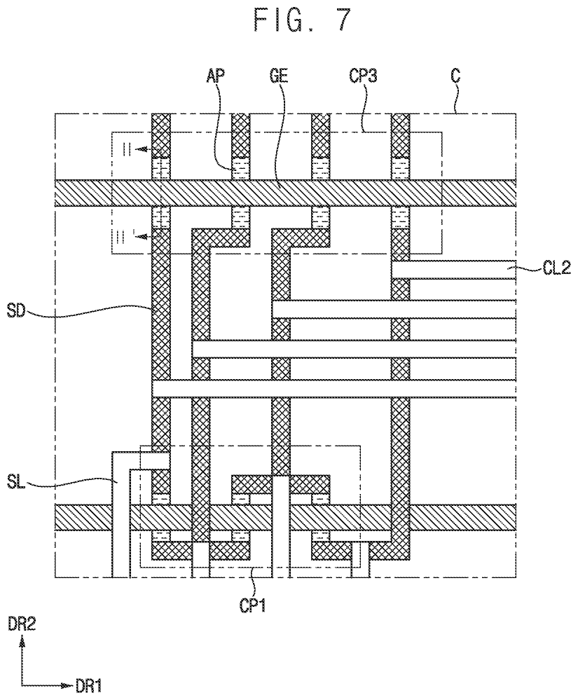

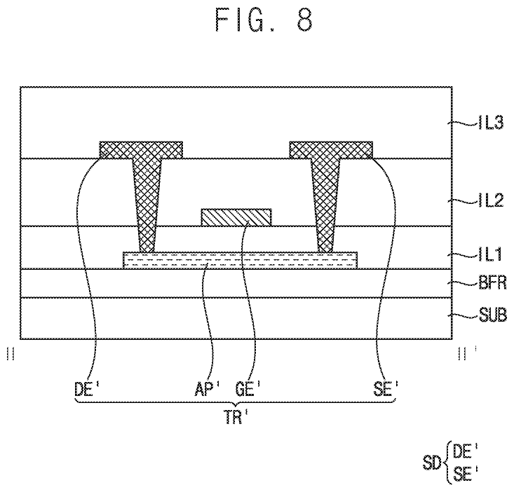

FIG. 7 is an enlarged plan view of area C of FIG. 4. FIG. 8 is a cross-sectional view taken along line II-II′ of FIG. 7. For example, FIG. 7 may be an enlarged plan view of the first control part CP1 and the third control part CP3, and FIG. 8 may be a cross-sectional view of the switching transistor included in the third control part CP3.

Hereinafter, descriptions overlapping those of the display device 10 described with reference to FIG. 3 will be omitted or simplified.

Referring to FIGS. 7 and 8, the display device 10 may include the substrate SUB, the buffer layer BFR, an active pattern AP′, the first insulating layer IL1, the gate electrode GE′, the second insulating layer IL2, a source-drain electrode SD and the third insulating layer IL3.

The buffer layer BFR, the active pattern AP′, the first insulating layer IL1, the gate electrode GE′, the second insulating layer IL2, the source-drain electrode SD and the third insulating layer may be sequentially disposed on the substrate SUB. The source-drain electrode SD may be connected to the signal line SL and the second connection line CL2. The source-drain electrode SD may include a source electrode SE′ and a drain electrode DE′.

The active pattern AP′, the gate electrode GE′, the source electrode SE′ and the drain electrode DE′ may form a transistor TR′. In an embodiment, for example, the transistor TR′ may be a switching transistor.

Although FIG. 7 illustrates that the source-drain electrode SD is disposed on a different layer from each of the signal line SL and the second connection line CL2, the configuration of the present disclosure is not limited thereto. In an embodiment, for example, the source-drain electrode SD may be disposed on the same layer as each of the signal line SL and the second connection line CL2 in another embodiment.

In the display device 10 according to an embodiment of the present disclosure, the first and second bump parts BP1 and BP2 included in the flexible printed circuit board FPC and the third and fourth bump parts BP3 and BP4 included in the driving integrated circuit IC may be connected to the first, second, third and fourth control parts CP1, CP2, CP3 and CP4, respectively. Each of the first, second, third and fourth control parts CP1, CP2, CP3 and CP4 may include the plurality of switching transistors, and the compression resistance of each of the first, second, third and fourth bump parts BP1, BP2, BP3 and BP4 may be selectively measured according to the operation of the switching transistors. Accordingly, since a relatively small number (e.g., four) of the test points TP may be required, emission characteristics (e.g., increased aperture ratio, narrow bezel, etc.) of the display device 10 may be effectively improved by securing a space of the flexible printed circuit board FPC.

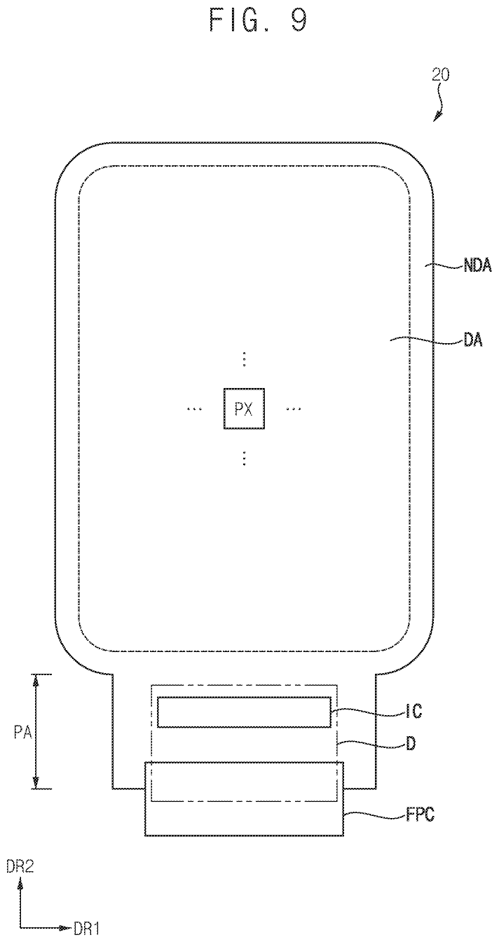

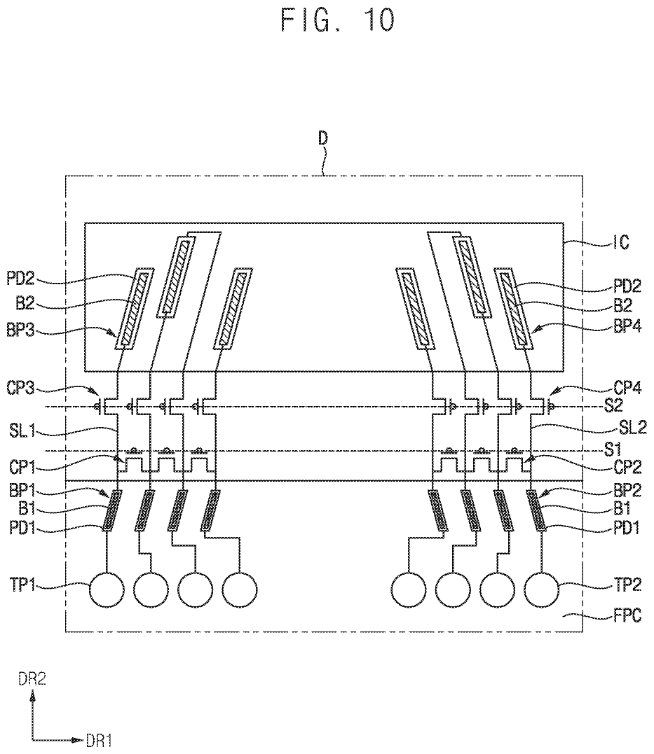

FIG. 9 is a plan view illustrating a display device according to another embodiment of the present disclosure. FIG. 10 is an enlarged plan view of an example of area D of FIG. 9. In an embodiment, for example, FIG. 10 may be an enlarged plan view of the pad area PA.

Hereinafter, descriptions overlapping those of the display device 10 described with reference to FIGS. 1, 2, 3, 4, 5 and 6 will be omitted or simplified.

Referring to FIGS. 9 and 10, a display device 20 may include a flexible printed circuit board FPC, a driving integrated circuit IC, a first signal line SL1, a second signal line SL2, a first control part CP1, a second control part CP2, a third control part CP3 and a fourth control part CP4.

The flexible printed circuit board FPC may include a first bump part BP1, a second bump part BP2, a plurality of first test points TP1 and a plurality of second test points TP2.

In an embodiment, the second bump part BP2 may be spaced apart from the first bump part BP1 in the first direction DR1. Each of the first bump part BP1 and the second bump part BP2 may include at least one first bump B1.

The first test points TP1 may be connected to the first bump part BP1, and the second test points TP2 may be connected to the second bump part BP2. In an embodiment, a number of each of the first test points TP1 and the second test points TP2 may be four. However, the configuration of the present disclosure is not limited thereto.

The driving integrated circuit IC may be disposed spaced apart from the flexible printed circuit board FPC in the second direction DR2. The driving integrated circuit IC may include a third bump part BP3 and a fourth bump part BP4.

In an embodiment, the fourth bump part BP4 may be disposed apart from the third bump part BP3 in the first direction DR1. Each of the third and fourth bump parts BP3 and BP4 may include at least one second bump B2.

The first signal line SL1 may be disposed between the first bump part BP1 and the third bump part BP3. The first signal line SL1 may connect the first bump part BP1 and the third bump part BP3. Accordingly, the first test points TP1 may be connected to each of the first bump part BP1 and the third bump part BP3. That is, resistance of each of the first bump part BP1 and the third bump part BP3 may be measured through the first test points TP1.

The second signal line SL2 may be disposed between the second bump part BP2 and the fourth bump part BP4. The second signal line SL2 may connect the second bump part BP2 and the fourth bump part BP4. Accordingly, the second test points TP2 may be connected to each of the second bump part BP2 and the fourth bump part BP4. That is, resistance of each of the second bump part BP2 and the fourth bump part BP4 may be measured through the second test points TP2.

Each of the first control part CP1 and the third control part CP3 may be disposed between the first bump part BP1 and the third bump part BP3. However, the present disclosure is not limited thereto. The first control part CP1 and the third control part CP3 may be disposed anywhere as long as the first control part CP1 is connected to the first bump part BP1, and the third control part CP3 is connected to the third bump part BP3. In addition, each of the first control part CP1 and the third control part CP3 may be connected to the first signal line SL1. That is, the first signal line SL1 may connect the first control part CP1 and the third control part CP3.

Each of the second control part CP2 and the fourth control part CP4 may be disposed between the second bump part BP2 and the fourth bump part BP4. However, the present disclosure is not limited thereto. The second control part CP2 and the fourth control part CP4 may be disposed anywhere as long as the second control part CP2 is connected to the second bump part BP2, and the fourth control part CP4 is connected to the fourth bump part BP4. In addition, each of the second control part CP2 and the fourth control part CP4 may be connected to the second signal line SL2. That is, the second signal line SL2 may connect the second control part CP2 and the fourth control part CP4.

In an embodiment, each of the first, second, third and fourth control parts CP1, CP2, CP3 and CP4 may include a plurality of transistors. In an embodiment, for example, each of the plurality of transistors may be a switching transistor.

Each of the first, second, third and fourth control parts CP1, CP2, CP3 and CP4 may receive the same control signal. In other words, the switching transistors included in one control part among the first, second, third and fourth control parts CP1, CP2, CP3 and CP4 may receive the same control signal. Specifically, the switching transistors included in each of the first control part CP1 and the second control part CP2 receive the same control signal as each other, and the switching transistors included in each of the third control part CP3 and the fourth control part CP4 may receive the same control signal as each other. In an embodiment, for example, the switching transistors included in the first control part CP1 and the second control part CP2 may receive a first signal S1 and the switching transistors included in the third control part CP3 and the fourth control part CP4 may receive a second signal S2.

In an embodiment, the first, second, third and fourth control parts CP1, CP2, CP3 and CP4 may control resistance measurement of the first, second, third and fourth bump parts BP1, BP2, BP3 and BP4 through the switching transistors, respectively.

In an embodiment, for example, the first signal S1 having a low level may be respectively applied to the first and second control parts CP1 and CP2, and the second signal S2 having a high level may be respectively applied to the third and fourth control parts CP3 and CP4. Accordingly, the switching transistors included in the first and second control parts CP1 and CP2 may be turned on, and the switching transistors included in the third and fourth control parts CP3 and CP4 may be turned off. In this case, resistance of each of the first and second bump parts BP1 and BP2 may be measured.

In addition, the second signal S2 having a low level may be respectively applied to the third and fourth control parts CP3 and CP4, and the second signal S2 having a high level may be respectively applied to the first and second control parts CP1 and CP2. Accordingly, the switching transistors included in the third and fourth control parts CP3 and CP4 may be turned on, and the switching transistors included in the first and second control parts CP1 and CP2 may be turned off. In this case, resistance of each of the third and fourth bump parts BP3 and BP4 may be measured. However, the present disclosure is not limited thereto.

In the display device 20 according to an embodiment of the present disclosure, the first and second bump parts BP1 and BP2 included in the flexible printed circuit board FPC and the third and fourth bump parts BP3 and BP4 included in the driving integrated circuit IC may be connected to the first, second, third and fourth control parts CP1, CP2, CP3 and CP4, respectively. Each of the first, second, third and fourth control parts CP1, CP2, CP3 and CP4 may include the plurality of switching transistors, and the compression resistances of the first and second bump parts BP1 and BP2 and/or the third and fourth bump parts BP3 and BP4 may be selectively measured according to the operation of the switching transistors. Accordingly, since a relatively small number of first and second test points TP1 and TP2 may be required, emission characteristics of the display device 20 may be effectively improved by securing a space of the flexible printed circuit board FPC.

The present disclosure can be applied to various display devices. In an embodiment, for example, the present disclosure is applicable to various display devices such as display devices for vehicles, ships and aircraft, portable communication devices, display devices for exhibition or information transmission, medical display devices, and the like.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the present invention. Accordingly, all such modifications are intended to be included within the scope of the present invention as defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. A display device comprising:
a substrate including a display area and a pad area, the pad area being located around the display area and adjacent to one side of the display area;
a flexible printed circuit board disposed in the pad area on the substrate and including a first bump part and a plurality of test points connected to the first bump part;
a driving integrated circuit disposed in the pad area on the substrate, spaced apart from the flexible printed circuit board and including a second bump part;
a signal line disposed in the pad area on the substrate and connecting the first bump part and the second bump part; and
a plurality of control parts disposed in the pad area on the substrate and connected to the signal line between the first bump part and the second bump part.

2. The display device of claim 1, wherein the plurality of control parts includes:
a first control part connected to the first bump part; and
a second control part connected to the second bump part.

3. The display device of claim 1, wherein a total number of the plurality of test points is four.

4. The display device of claim 2, wherein the flexible printed circuit board further includes a third bump part spaced apart from the first bump part, and the driving integrated circuit further includes a fourth bump part spaced apart from the second bump part.

5. The display device of claim 4, further comprising:
a first connection line connecting the first bump part and the third bump part.

6. The display device of claim 5, further comprising:
a second connection line spaced apart from the first connection line and connecting the second bump part and the fourth bump part.

7. The display device of claim 4, further comprising:
a third control part connected to the third bump part and a fourth control part connected to the fourth bump part.

8. The display device of claim 7, wherein each of the first, second, third and fourth control parts includes a plurality of transistors.

9. The display device of claim 8, wherein each of the plurality of transistors is a switching transistor.

10. The display device of claim 8, wherein the plurality of transistors included in one control part among the first, second, third and fourth control parts receive a same signal.

11. A display device comprising:
a substrate including a display area and a pad area, the pad area being located around the display area and adjacent to one side of the display area;
a flexible printed circuit board disposed in the pad area on the substrate and including a first bump part, a second bump part spaced apart from the first bump part, a plurality of first test points connected to the first bump part and a plurality of second test points connected to the second bump part;
a driving integrated circuit disposed in the pad area on the substrate, spaced apart from the flexible printed circuit board and including a third bump part and a fourth bump part spaced apart from the third bump part;
a signal line disposed in the pad area on the substrate and connecting the first bump part and the third bump part and connecting the second bump part and the fourth bump part; and
a plurality of control parts disposed in the pad area on the substrate and connected to the signal line.

12. The display device of claim 11, wherein the plurality of control parts includes:
a first control part connected to the first bump part;
a second control part connected to the second bump part;
a third control part connected to the third bump part; and
a fourth control part connected to the fourth bump part.

13. The display device of claim 11, wherein a total number of the plurality of first test points and a total number of the plurality of second test points each are four.

14. The display device of claim 12, wherein the signal line includes a first signal line and a second signal line spaced apart from the first signal line, and
wherein the first signal line connects the first bump part and the third bump part, and the second signal line connects the second bump part and the fourth bump part.

15. The display device of claim 14, wherein the first signal line connects the first control part and the third control part.

16. The display device of claim 15, wherein the second signal line connects the second control part and the fourth control part.

17. The display device of claim 12, wherein each of the first, second, third and fourth control parts includes a plurality of transistors.

18. The display device of claim 17, wherein each of the plurality of transistors is a switching transistor.

19. The display device of claim 17, wherein the plurality of transistors included in one control part among the first, second, third and fourth control parts receive a same signal.

20. The display device of claim 19, wherein the plurality of transistors included in each of the first control part and the second control part receive a first signal, and the plurality of transistors included in each of the third control part and the fourth control part receive a second signal.
